(19) United States
(12) Patent Application Publication
(10) Pub. No.: US 2007/0081401 A1
(43) Pub. Date: Apr. 12, 2007

(54) APPARATUS FOR CONTROLLING FLASH MEMORY AND METHOD THEREOF

(75) Inventor: Yuan-Cheng Chen, Hsinchu County (TW)

Correspondence Address: J C PATENTS, INC., 4 VENTURE, SUITE 250, IRVINE, CA, 92618, US

(73) Assignee: SUNPLUS TECHNOLOGY CO., LTD., Hsinchu (TW)

(21) Appl. No.: 11/465,580

(22) Filed: Aug. 18, 2006

(30) Foreign Application Priority Data
Oct. 12, 2005 (TW) 94135484

(51) Int. Cl. G11C 7/00

(52) U.S. Cl. 365/200

(57) ABSTRACT

An apparatus for controlling a flash memory and the method thereof are disclosed. The flash memory includes a plurality of blocks which are divided into a plurality of storage blocks and a plurality of spare blocks. The apparatus includes a bad block mapping table and a controller. When a data is to be accessed based on an accessed block address, the controller determines whether the block corresponding to the accessed block address is a damaged block. When the controller determines that the block corresponding to the accessed block address is a damaged block, the controller searches the bad block mapping table based on the accessed block address to find the address of the corresponding spare block for replacing the accessed block address.

### CROSS-REFERENCE TO RELATED APPLICATION

This application claims the priority benefit of Taiwan application serial no. 94135484, filed on Oct. 12, 2005. All disclosure of the Taiwan application is incorporated herein by reference.

### BACKGROUND OF THE INVENTION

1. Field of Invention

The present invention relates to a flash memory. More particularly, the present invention relates to an apparatus for controlling a flash memory and the method thereof.

2. Description of Related Art

Along with the widespread popularity of electronic consumer products, the requirement for data storage has been accordingly increased. The storage capacity of flash memory is increased because of the rapid advancement in the fabricating technology thereof. And flash memory has become very popular due to its characteristics as small volume and low electricity consumption. However, presently, the semiconductor manufacturing process cannot yet guarantee that every storage block in a flash is qualified for use when the flash memory is manufactured. In addition, the number of writings and erasings for each storage block has limits, and the storage block may be damaged when it reaches its lifetime. Thus, conventionally, if an electronic consumer product with a flash memory as its storage medium is to be developed, the control apparatus for the flash memory has to use very large memory to manage the storage space thereof.

FIG. 1 is a schematic block diagram of a conventional flash memory. The flash memory 10 has a plurality of blocks, for example, a flash memory of 128 Mb has more than 8,000 blocks 101. Each block is further divided into a plurality of pages 102, generally 8 to 64 pages. And each page is divided into a data storage area 103 and a spare area 104. Generally speaking, the page has two specifications: if the data storage area is 512 bytes, then the spare area is 16 bytes; if the data storage area is 2048 bytes, then the spare area is 64 bytes. One of the functions of the spare area is served as the error correction code of the data storage area. Another function is to mark non-FF value in the first page or the second page (if the first page is damaged) when the block is damaged so as to indicate that this block is a damaged block.

Generally speaking, an erase action is taken before writing into a flash memory, so that all the memory cells are programmed to logic 1. The flash memory erases in units of pages and writes in units of blocks. It is possible to convert the status of logic 1 into the status of logic 0, but impossible to convert the status of logic 0 to the status of logic 1 due to physical characteristics of the flash memory. If data is to be written into a page with the status of logic 0 in a particular block, the entire block has to be erased before the data is written. This is the characteristic of flash memory. However, frequent erase actions may result in damaged blocks.

The biggest problem in using flash memory is the occurrence of damaged blocks. Damaged blocks may have been already existed when the flash memory is manufactured, or may happen during using of the flash memory. Generally speaking, the manufacturer will guarantee that the damaged block ratio is to be under 2%. Nevertheless, from the user's point of view, the user does not anticipate that the data is unable to be stored continuously into the flash memory. For a general user, the data has to be stored into the flash memory continuously. However, presently, the semiconductor manufacturing process cannot guarantee that each block is qualified and usable. Thus, the space in a flash memory is not continuous; instead, good blocks and damaged blocks are used alternately. If, however, the user unfortunately stores the data (or part of the data) into a damaged block, the data will be damaged that is not acceptable.

To solve the inconvenience of using the product induced by damaged blocks, M-Systems Flash Disk Pioneers Ltd. has disclosed the solution in U.S. Pat. No. 5,404,485. In addition, SSFDC Forum proposed the SmartMedia Format specification. The two solutions both use a virtual map and an allocation map. The virtual map eliminates the blocks which are damaged when they are being manufactured or during the using mainly through not listing the blocks in the map. And the allocation map is mainly used for recording the status of each block so as to speed up the searching for new blocks when writing into a block, so that the storing speed can be increased.

Even though the aforementioned two methods can effectively resolve the problem using damaged blocks in the flash memory. However, the capacity of a, for example, 128 Mb flash memory is 8192 blocks and each block is 16 Kb, the mapping table for this flash memory in units of blocks needs a memory of at least 16 Kb, i.e. 8192*2 bytes. If two-layer mapping of blocks and pages is used, a memory of 24 Kb, i.e. 8192*3 bytes, is needed. The allocation map needs a 2Kb memory space. Accordingly, if the aforementioned methods are used, the total memory required is at least 18 Kb. Such a large memory cannot be provided in many embedded products. Accordingly, a flash memory control apparatus and control method with lower memory requirement are needed.

### SUMMARY OF THE INVENTION

Accordingly, the present invention is directed to provide an apparatus for controlling a flash memory for reducing the cost.

According to another aspect of the present invention, a method for controlling a flash memory is provided, which can prevent the user from using damaged blocks.

The present invention provides an apparatus for controlling a flash memory. The flash memory includes a plurality of blocks, wherein these blocks are divided into a plurality of storage blocks and a plurality of spare blocks. The apparatus includes a bad block mapping table and a controller. The controller determines whether the block corresponding to an accessed block address is a damaged block when a data is to be accessed based on the accessed block address. When the controller determines that the block corresponding to the accessed block address is a damaged block, the controller searches the bad block mapping table based on the accessed block address to find the address of the corresponding spare block for replacing the accessed block address. The controller repeats the actions described above until the spare block corresponding to the accessed block address is a normal block. Then, the data is accessed based on the accessed block address.

According to the flash memory control apparatus in an exemplary embodiment of the present invention, the foregoing bad block mapping table includes a plurality of mapping units, and each mapping unit includes a damaged block address storage area and a spare block address storage area. When the controller searches the bad block mapping table for the accessed block address, the controller scans the damaged block address stored in the damaged block address storage area of each mapping unit to find the corresponding spare block address stored in the corresponding spare block address storage area as the accessed block address.

The present invention provides a method for controlling a flash memory. The flash memory includes a plurality of blocks, wherein these blocks are divided into a plurality of storage blocks and a plurality of spare blocks. The control method includes at least the following steps. First, a bad block mapping table is provided. When a data is to be accessed based on an accessed block address, the block corresponding to the accessed block address is determined whether it is a damaged block. When the block corresponding to the accessed block address is a damaged block, the bad block mapping table is searched based on the accessed block address to find the address of the corresponding spare block for replacing the accessed block address. After that, the actions described above are repeated until the spare block corresponding to the accessed block address is a normal block. Then, the data is accessed based on the accessed block address.

According to the flash memory control method in an exemplary embodiment of the present invention, the foregoing bad block mapping table includes a plurality of mapping units, and each mapping unit includes a damaged block address storage area and a spare block address storage area. When the block corresponding to the accessed block address is a damaged block, the damaged block address stored in the damaged block address storage area of each mapping unit in the bad block mapping table is scanned based on the accessed block address to find the corresponding spare block address stored in the corresponding spare block address storage area as the accessed block address for replacing the original accessed block address.

A simple bad block mapping table is adopted in the present invention. When the user is accessing data, first, the controller detects whether the storage block is a damaged block. If it is damaged, the spare block is then located by searching the bad block mapping table, so that a user is prevented from using the damaged blocks. In addition, since the bad block mapping table only stores the information of damaged blocks, which means the other undamaged blocks are not stored in the map, accordingly, the method and apparatus in the present invention use less storage space compared to the conventional method and apparatus which have to store all the address information. In summary, the present invention saves a lot of memory space while achieving the function of preventing the user from using damaged blocks.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic block diagram of a conventional flash memory.

FIG. 2 is a block diagram illustrating the circuit of a flash memory control apparatus according to an embodiment of the present invention.

FIG. 3 illustrates an embodiment method of the bad block mapping table 202 in FIG. 2 according to an embodiment of the present invention.

FIG. 4 illustrates an embodiment method of the bad block mapping table 202 in FIG. 2 according to an embodiment of the present invention.

FIG. 5 illustrates an embodiment method of the bad block mapping table 202 in FIG. 2 according to an embodiment of the present invention.

FIG. 6 is a circuit block diagram of a flash memory control apparatus according to an embodiment of the present invention.

FIG. 7 illustrates an embodiment method of the bad block mapping table 602 in FIG. 6 according to an embodiment of the present invention.

FIG. 8 is a flowchart illustrating a flash memory control method according to an embodiment of the present invention.

FIG. 9 is a flowchart illustrating a flash memory control method according to an embodiment of the present invention.

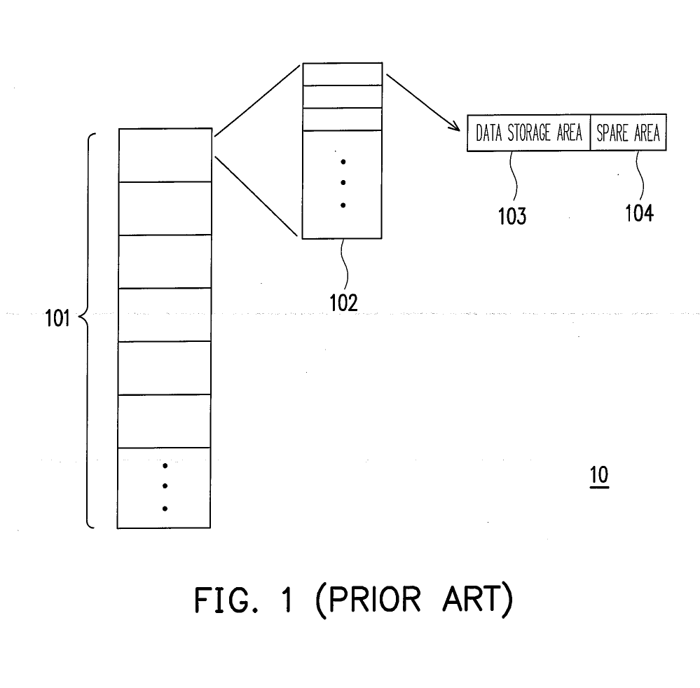

### DESCRIPTION OF EMBODIMENTS

In the prior art, to prevent the user from using damaged blocks, all the storage blocks are listed in the mapping table to eliminate damaged blocks, so that a great amount of memory is wasted in managing the mapping table. As a result, the hardware cost is inevitably increased. Thus, the present invention provides an apparatus and a method for controlling flash memory to achieve the purpose of “preventing the user from using damaged blocks” with lower hardware cost. The detailed implementation method is explained with reference to the following embodiments.

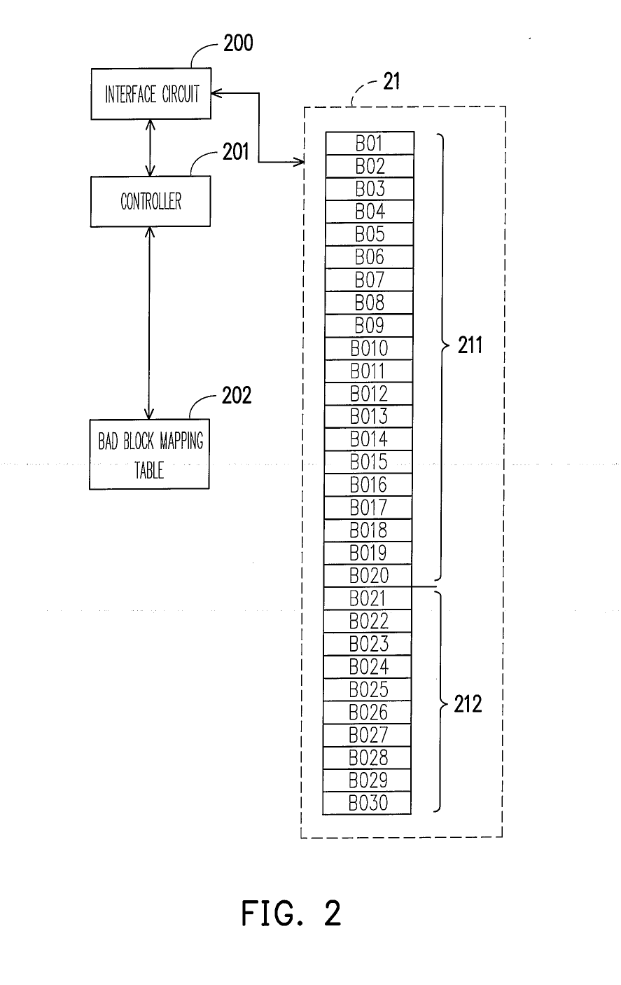

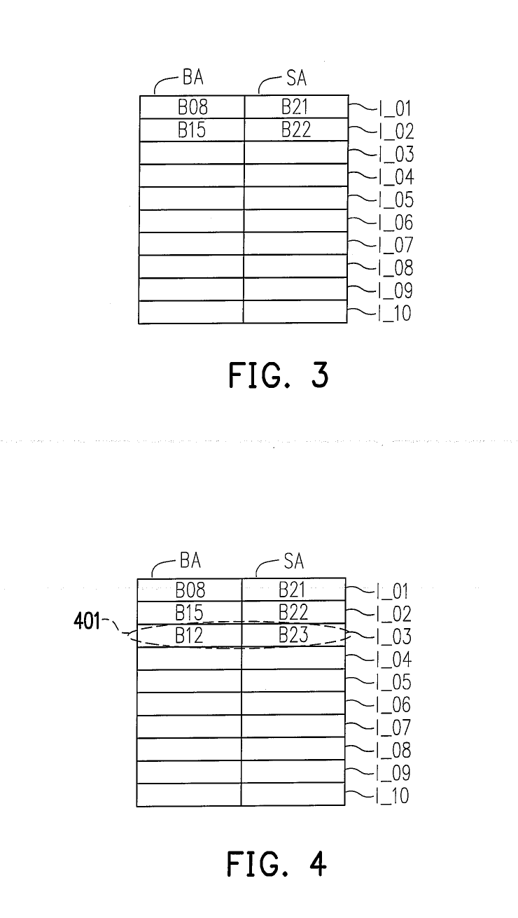

FIG. 2 is a block diagram illustrating the circuit of a flash memory control apparatus according to an embodiment of the present invention. Referring to FIG. 2, the circuit of the present embodiment includes an interface circuit 200, a controller 201, a bad block mapping table 202 and a flash memory block 21 controlled by the controller. The flash memory block 21 is divided into a plurality of storage blocks 211 to be used by the user and a plurality of spare blocks 212 to be used in case there are damaged blocks. In addition, FIG. 3 is an embodiment of the bad block mapping table 202. In the present embodiment, a plurality of mapping units I_01 to I_10 are included, and each mapping unit includes a damaged block address storage area BA and a spare block address storage area SA.

To simplify the illustration, the embodiment in FIG. 2 uses a small number of storage blocks (20 blocks) and a small number of spare blocks (10 blocks) as example, wherein the storage blocks 211 is marked as B01 to B20 and the spare blocks 212 is marked as B21 to B30. Similarly, the embodiment in FIG. 3 also uses a small number of mapping units (10 mapping units) I_01 to I_10 as example. However, since a typical flash memory of 128 Mb has more than 8,000 storage blocks, the present embodiment is only for the convenience of description and the present invention should not be limited by the embodiment.

Please refer to FIG. 2 and FIG. 3. First, when the apparatus is being started up, the apparatus is, for example, a Universal Serial Bus (USB) flash drive, and the interface circuit is a USB interface circuit. When the apparatus is plugged into a computer through a USB port for the first time, the computer starts to supply electricity to the flash drive. Here, the controller 201 scans whether there is any damaged block among the storage blocks B01 to B20 to be used by the user in the flash memory block 21. If any block is damaged, non-FF value is marked in the spare area of the first page or the second page of the damaged block. When the controller 201 finds non-FF value in the spare area of the first page of, for example, the 8^{th} storage block B08, then the 8^{th} storage block B08 is determined as a damaged block. After that, the controller 201 stores the address of the 8^{th} storage block in the damaged block address storage area BA of the mapping unit I_01 in the bad block mapping table 202, and allocates a spare block, for example, the first spare block B21 for replacing the 8^{th} storage block B08, and stores the address of B21 into the spare block address storage area SA of the mapping unit I_01.

Next, the controller 201 continues to scan the flash memory block 21, and finds that the 15^{th} storage block B15 is a damaged block, then the controller 201 performs the same actions as to the 8^{th} storage block to store the address of the 15^{th} storage block to the damaged block address storage area BA of the mapping unit I_02 in the bad block mapping table 202 and allocates a spare block, for example, the 2^{nd} spare block B22 for replacing the 15^{th} storage block B15, and stores the address of B22 into the spare block address storage area SA of the mapping unit I_02 for query.

When the flash drive is being used as normal, e.g. when the user is to access the flash drive through the computer, the user drags a file into the flash drive through the file manager of the operating system Windows. Here, a command is sent to the controller 201 through the interface circuit 200 to notify the controller 201 that a file is to be stored and is to be stored in the address of, for example, the 8^{th} storage block. Then the controller 201 checks the 8^{th} storage block B08 in the flash memory block 21 based on the accessed block address. If the controller 201 finds the block is a damaged block, it checks the damaged block address storage area BA of all the mapping units I_01 to I_10 in the bad block mapping table 202 to find whether there is any address matching the address of the 8^{th} storage block B08. If the controller 201 finds the address of the 8^{th} storage block B08 in the mapping unit I_01, it checks the spare block address storage area SA corresponding to B08 to find out the address of the first spare block B21 for replacing the accessed block address of the 8^{th} storage block B08. After that, the controller 201 checks whether the spare block B21 is a damaged block. If the controller 201 confirms that the spare block B21 is a valid block (not damaged), it controls the interface circuit 200 to store the data into the first spare block B21.

Next, the user drags a larger file into the flash drive through the file manager of the computer operating system Windows. Here, a command is sent to the controller 201 through the interface circuit 200 to notify the controller 201 that a file is to be stored and is to be stored in the addresses of, for example the 10^{th} to 15^{th} storage blocks B10 to B15. Then the controller 201 checks in sequence whether the 10^{th} to 15^{th} storage blocks B10 to B15 are damaged blocks based on these addresses. If these blocks are not damaged, the data is stored into these blocks.

Assuming that the 12^{th} storage block B12 is found a damaged block, similarly, the controller 201 searches the bad block mapping table 202. Here, because the address of the 12^{th} storage block B12 is not stored in the bad block mapping table 202, the controller 201 sets up a mapping relation in the unused mapping unit I_03 in the bad block mapping table 202, as 401 shown in FIG. 4. The address of B12 is written into the damaged block address storage area BA of the mapping unit I_03, and the address of the 3^{rd} spare block B23 is stored into the spare block address storage area SA thereof so as to provide the mapping relation. Then, the controller 201 replaces the 12^{th} storage block B12 with the 3^{rd} spare block B23. Next, the controller 201 checks whether the 3^{rd} spare block is a damaged block. If the 3^{rd} block is not damaged, the data to be originally stored into the 12^{th} storage block B12 is stored into the 3^{rd} spare block B23.

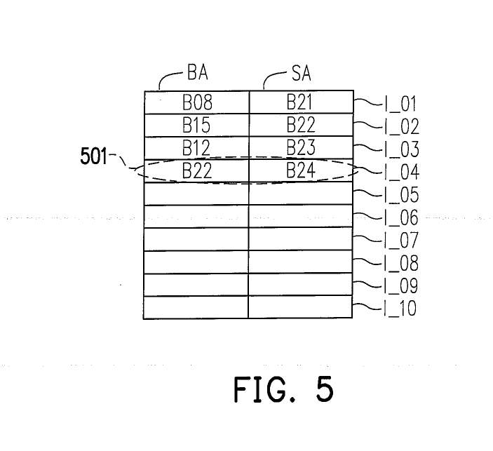

Next, the foregoing steps are repeated until the 15^{th} storage block B15 is reached, the controller 201 finds that the block B15 is damaged, so it searches the bad block mapping table 202 to find out the corresponding address thereof is the address of the 2^{nd} spare block B22. After that, the controller 201 checks whether the 2^{nd} spare block B22 is a damaged block. If this block is found a damaged block, the controller 201 continues to search the bad block mapping table 202 and finds it is impossible to find the corresponding spare block of the 2^{nd} spare block B22, similarly, the controller 201 sets up a mapping relation in the mapping unit I_04 in the bad block mapping table 202, as 501 shown in FIG. 5. Wherein, the address of B22 is written into the damaged block address storage area BA, and the address of the 4^{th} spare block B24 is stored into the spare block address storage area SA so as to provide a mapping relation. The controller 201 then replaces the 22^{nd} spare block B22 with the 4^{th} spare block B24. Next, the controller 201 checks whether the 4^{th} spare block is a damaged block. If not, the data to be originally stored into the 15^{th} storage block B15 is stored into the 4^{th} spare block B24.

The above embodiment illustrates the action for reading; the embodiment for storing action is similar as the embodiment described above. When the user double-clicks on a file, e.g. a MP3 file, in the flash drive through the file manager of the computer operating system Windows to activate WinAmp software to play the file, a read command is sent to the controller 201 through the interface circuit 200. The controller 201 receives the address of the file to be read (e.g. the address of the 15^{th} storage block B15) and checks whether the 15^{th} storage block b15 is a damaged block. If the controller 201 finds out that the 15^{th} storage block B15 is damaged, it queries the mapping relation in the bad block mapping table 202 and finds that block B22 is the replacing block for the block B15. After that, the controller 201 checks again whether the block B22 is damaged. Similarly, the controller 201 finds out that the block B22 is also a damaged block, thus the controller 201 searches the bad block mapping table 202 once more to find that block B24 is the replacing block for block B22. The controller 201 checks again whether block B24 is a damaged block, and finds that block B24 is not damaged, so that the controller 201 reads data in B24 for the application program WinAmp to play the MP3 music.

In the present embodiment, it is remarkable that the mapping table in the present embodiment can be implemented with only a small quantity of memory. In the conventional technology, the mapping table has to arrange all the space in the flash memory, which means the larger the flash memory, the larger the memory needed by the mapping table. In the present embodiment, the maximum value of the memory required by the mapping table is only determined by the number of spare blocks. Accordingly, if there are 2% damaged blocks in a flash memory when the flash memory is manufactured, according to the product warranty, a certain amount of spare blocks can be arranged to ensure that the product can be used by the users properly within the warranty period.

Use an MP3 flash drive as an example. Generally, after an MP3 is put into the flash drive, the user may only listen to the music from the flash drive without doing any erase action for the whole week. Thus, 3% spare blocks can be selected in the flash memory, wherein 2% is for the damage rate during manufacturing process. Another 1% can be prepared for, for example, 3 years warranty. Taking the MP3 flash drive described above as an example, the bad block mapping table needs only 3% of that in the conventional technology. In addition, the characteristic of the bad block mapping table is that when there is a damaged block, the damaged block will be written into the mapping table. In other words, the mapping table is not required to be updated. The action of the controller is to keep checking whether there is any damaged block in the flash memory. If there is a damaged block, then the controller searches the mapping table; otherwise, the data is accessed. Thus, this type of bad block mapping table is very suitable to be stored in read-only memory, for example, the map can be built in the flash memory directly without taking erase action. Thus, the embodiments in the present invention can be implemented without any external (or built-in) RAM.

Moreover, according to the embodiment of the present invention, even though the spare blocks listed in the mapping unit of the bad block mapping table in the present embodiment are incremental, that is, the spare block address stored in the spare block storage area SA of I_01 is B21, the spare block address stored in the spare block storage area SA of I_02 is B22, . . . . However, the present invention does not have to be implemented in this way. For example, the present invention can be implemented in degressive manner, that is, the spare block address stored in the spare block storage area SA of I_01 is B30, the spare block address stored in the spare block storage area SA of I_02 is B29 . . . or in random manner. Similarly, it is not necessary for the bad block mapping table to be stored in sequence.

However, in the embodiment described above, the method of storing the mapping table in sequence has one advantage. Generally speaking, the flash memory can perform a complete erase action at initialization, i.e. all the memory cells of the flash memory are in the status of, for example, logic 1. Thus, when a file is to be written into the flash memory, some sections (some pages in a particular block) can be changed to logic 0 based on the address. However, if a file is to be edited, i.e. a stored file is to be edited, the portion changed to logic 0 cannot be changed to logic 1 again. However, erasing is calculated in blocks because writing is calculated in pages except that erasing takes much longer than writing does. Accordingly, assuming that the file the user wants to edit only takes 2 pages, all the other data stored in this block needs to be erased all together. Thus, conventionally, after a file has been edited, the entire block, except the edited file, is put into the memory of the computer, and then after the block is erased, the block stored in the memory of the computer and the edited file are written into the block again.

However, when the present invention is implemented as the embodiments described above, the unused spare blocks can be defined clearly. For example, in the present embodiment, there are 6 unused spare blocks B25 to B30, which can be served as data switch area. Assuming that the file to be edited is stored in the 5^{th} page of B17, after the file has been edited, the edited file and the data in the entire block B17 except the edited file are written into the spare block B25. Next, after erasing the block B17, the data in block B25 is written into B17. If, unfortunately, there is a power cutoff when writing to B17, data recovery operation can be performed. In addition, the switch area can be used in sequence. If block B25 is used as the switch area this time, B26 can be used as the switch area next time, followed by B27, . . . . In this way, spare blocks are used and erased sequentially and repeatedly. Accordingly, the damages of the spare blocks can be reduced because the spare blocks are evenly used.

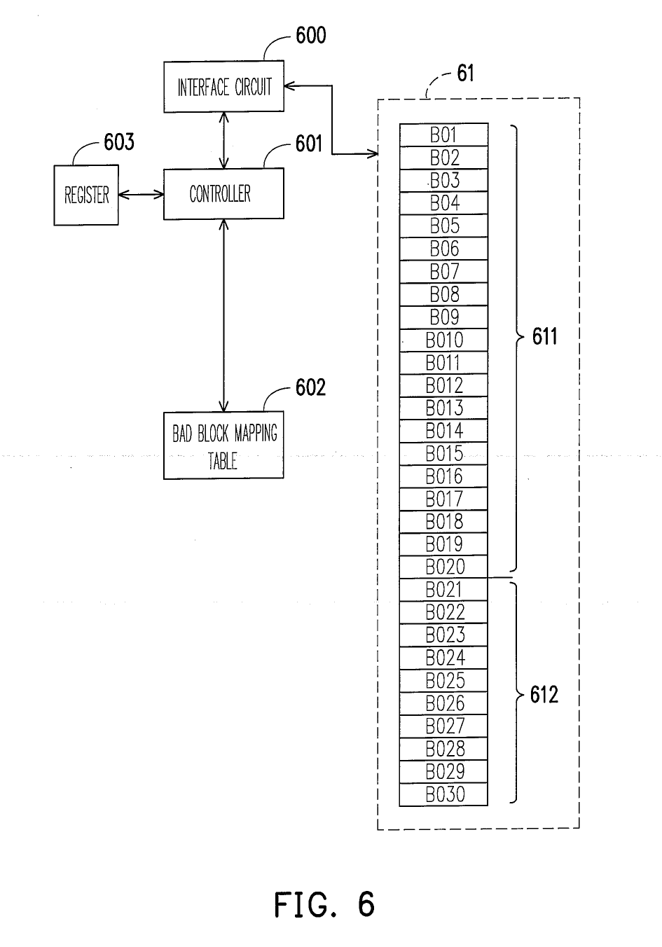

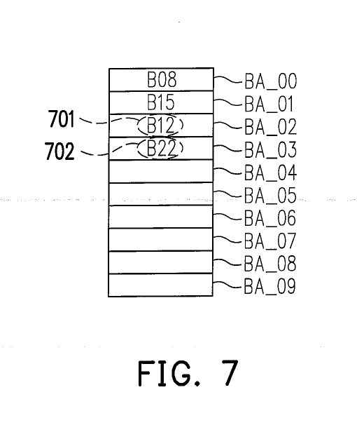

Another embodiment can further reduce the memory capacity of the bad block mapping table when the mapping table is stored incrementally and sequentially as described above. The circuit thereof is similar to the embodiment in FIG. 2. However, besides the flash memory block 61, the controller 601, the interface circuit 600 and the bad block mapping table 602 shown in FIG. 2, a register 603 is added for providing the address of the first spare block B21. The flash memory block 61 still uses 20 storage blocks 611 (B01 to B20) and 10 spare blocks 612 (B21 to B30) as example. Because the circuit is implemented as shown in FIG. 6, the bad block mapping table can be implemented as illustrated in FIG. 7.

Referring to FIG. 6 and FIG. 7, similarly, if the apparatus is, for example, a Universal Serial Bus (USB) flash drive, the interface circuit 600 is a USB interface circuit. Similarly, assuming that the 8^{th} and the 15^{th} blocks are damaged blocks. In the same way as in the previous embodiment, at start-up, the controller 601 scans all the storage blocks first and stores the addresses of damaged blocks into the bad block mapping table. Thus, the 1^{st} damaged block address storage area BA_00 of the bad block mapping table 602 stores the address of the 8^{th} storage block. The 2^{nd} damaged block address storage area BA_01 of the bad block mapping table 602 stores the address of the 15^{th} storage block.

For example, if the user wants to access the flash drive through the computer, the user drags a file into the flash drive through the file manager of the operating system Windows. Here, a command is sent to the controller 601 through the interface circuit 600 to notify the controller 601 that a file is to be stored and is to be stored in the address of the, for example, 8^{th} storage block. Then, the controller 601 checks the 8^{th} storage block B08 in the flash memory block 61. If the controller 601 finds the block is damaged, the controller 601 searches the damaged block address storage areas BA_00 to BA_09 in the bad block mapping table 602 to check whether there is an address matching the address of the 8^{th} storage block B08. If the controller 601 finds that the address of the 8^{th} storage block is in the 0^{th} damaged block address storage area BA_00, the controller 601 reads the address of the 1^{st} spare block stored in the register 603, and adds 0 to the address as the accessed block address. The controller 601 finds the spare block B21 based on the accessed block address, and checks whether the block B21 is a damaged block. If the controller 601 confirms that B21 is a valid block (not damaged), the controller 601 controls the interface circuit 600 to store the data into the first spare block B21.

Similarly, the embodiment described above will be explained as an example. The user drags a larger file into the flash drive through the file manager of the computer operating system Windows. Here, a command is sent to the controller 601 through the interface circuit 600 to notify the controller 601 that the file is to be stored and is to be stored in the addresses of, for example, the 10^{th} to 15^{th} storage blocks B10 to B15. Then, the controller 601 checks whether the 10^{th} to 15^{th} storage blocks B10 to B15 are damaged blocks based on these addresses sequentially; if not, the data is stored into these blocks.

Assuming that the 12^{th} storage block B12 is found a damaged block, similarly, the controller 601 searches the bad block mapping table 602. Here, because the address of the 12^{th} storage block B12 is not stored in the bad block mapping table 202, the controller 601 stores the address of the 12^{th} storage block B12 into the 2^{nd} damaged block address storage area BA_02 of the bad block mapping table 602, as 701 shown in FIG. 7. And the controller 601 adds 2 to the address of the 1^{st} spare block, i.e. the address of the 3^{rd} spare block, as the new accessed block address. Next, the controller 601 checks whether the 3^{rd} spare block is a damaged block; if not, the data to be originally stored into the 12^{th} storage block B12 is stored into the 3^{rd} spare block B23.

Next, assume that both the 13^{th} and the 14^{th} blocks are not damaged. The controller 601 starts to process the 15^{th} storage block. If the controller 601 finds that the block B15 is damaged, it searches the bad block mapping table 602 to find out that the address of B15 is stored in the 1^{st} damaged block address storage area BA_01, thus the corresponding address can be calculated as the spare block address stored in the register plus 1, i.e. the address of the 2^{nd} spare block B22. Next, the controller 601 checks whether the 2^{nd} spare block B22 is damaged. If the block is damaged, the controller 601 continues searching the bad block mapping table 602. Here, the controller 601 finds that the address of the 2^{nd} spare block B22 cannot be found, similarly, the controller 601 stores the address of the 2^{nd} spare block B22 into the damaged block address storage area BA_03 of the bad block mapping table 602, as 702 shown in FIG. 7. The controller calculates the address of the 4^{th} spare block B24 in the same way to replace the address of the 22^{nd} spare block B22 as the accessed block address. The controller 601 checks whether the 4^{th} spare block is a damaged block based on the accessed block address; if not, the data to be originally stored into the 15^{th} storage block is stored into the 4^{th} spare block B24.

The embodiment in FIG. 6 is for storing action, and the embodiment for writing action is similar with the described embodiment, so the details will not be further described. In the present embodiment, the memory usage of the bad block mapping table can be further reduced. Similarly, since the starting addresses of the spare blocks stored in the bad block mapping table and the register need not to be updated, thus both are suitable to be used in the flash memory. Accordingly, the embodiments of the present invention can be implemented without any external (or built-in) RAM.

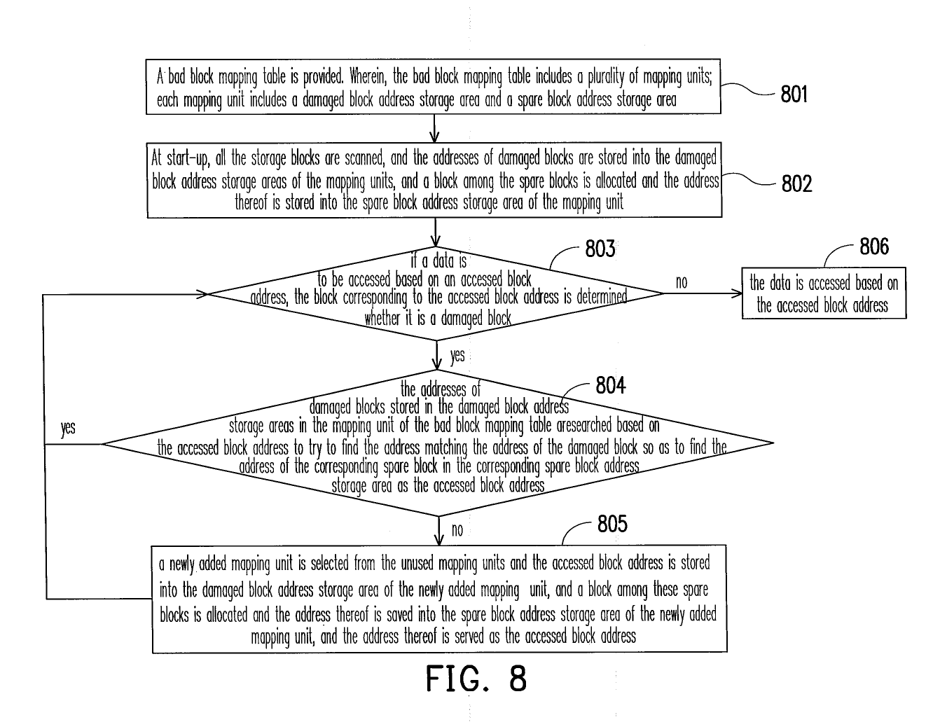

The embodiment of the flash memory control apparatus described above is only an embodiment provided based on the spirit of the present invention. The present invention further provides a method embodiment for controlling the flash memory. FIG. 8 is a flowchart illustrating a flash memory control method according to an embodiment of the present invention, the flowchart is an embodiment of the method when the bad block mapping table is as shown in FIG. 3. Referring to FIG. 8, first, a bad block mapping table is provided. Wherein, the bad block mapping table includes a plurality of mapping units; each mapping unit includes a damaged block address storage area and a spare block address storage area (step 801). At start-up, all the storage blocks are scanned, and the addresses of damaged blocks are stored into the damaged block address storage areas of the mapping units, and a block among the spare blocks is allocated and the address thereof is stored into the spare block address storage area of the mapping unit (step 802).

Next, if a data is to be accessed based on an accessed block address, the block corresponding to the accessed block address is determined whether it is a damaged block (step 803). If the block corresponding to the accessed block address is determined to be a damaged block in the previous step, the addresses of damaged blocks stored in the damaged block address storage areas in the mapping unit of the bad block mapping table are searched based on the accessed block address to try to find the address matching the address of the damaged block so as to find the address of the corresponding spare block in the corresponding spare block address storage area as the accessed block address (step 804); return to step 803 if the address is found.

If no address matching the address of the damaged block is found in the bad block mapping table for finding the corresponding accessed block address, then a newly added mapping unit is selected from the unused mapping units and the accessed block address is stored into the damaged block address storage area of the newly added mapping unit, and a block among these spare blocks is allocated and the address thereof is saved into the spare block address storage area of the newly added mapping unit, and the address thereof is served as the accessed block address (step 805), then return to step 803. The actions described above are repeated until the spare block corresponding to the accessed block address is a normal block, and then the data is accessed based on the accessed block address (step 806).

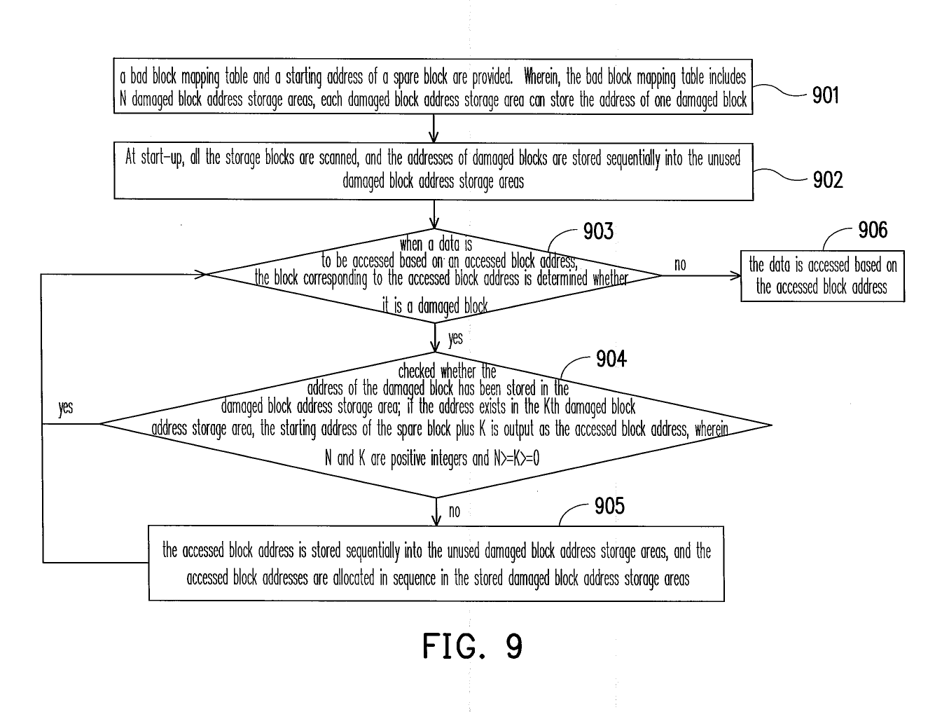

When the bad block mapping table is as shown in FIG. 7, the embodiment of the flash memory control method is revised as the flowchart shown in FIG. 9. FIG. 9 is a flowchart illustrating a flash memory control method according to an embodiment of the present invention. First, a bad block mapping table and a starting address of a spare block are provided. Wherein, the bad block mapping table includes N damaged block address storage areas, each damaged block address storage area can store the address of one damaged block (step 901). At start-up, all the storage blocks are scanned, and the addresses of damaged blocks are stored sequentially into the unused damaged block address storage areas (step 902).

Next, when a data is to be accessed based on an accessed block address, the block corresponding to the accessed block address is determined whether it is a damaged block (step 903). If the block corresponding to the accessed block address is determined as a damaged block in the previous step, checked whether the address of the damaged block has been stored in the damaged block address storage area; if the address exists in the K^{th} damaged block address storage area, the starting address of the spare block plus K is output as the accessed block address, wherein N and K are positive integers and N>=K>=0 (step 904), and then return to step 903. If the accessed block address cannot be found in the bad block mapping table, the accessed block address is stored sequentially into the unused damaged block address storage areas, and the accessed block addresses are allocated in sequence in the stored damaged block address storage areas (step 905); then return to step 903. The actions described above are repeated until the spare block corresponding to the accessed block address is a normal block, and the data is accessed based on the accessed block address (step 906).

In overview, the present invention adopts a simple bad block mapping table. When the user is accessing data, the controller detects whether the storage block is a damaged block first; if the storage block is a damaged block, the controller searches the bad block mapping table to locate the spare block. Thus, the present invention prevents the user from using damaged blocks. In addition, since the bad block mapping table only stores the information of damaged blocks, that is, the other undamaged blocks are not stored in the table. Compared with the conventional method of storing the information of all the addresses in the table, which wastes a lot of memory, the method and apparatus in the present invention uses less storage space to achieve the same function of preventing the user from using damaged blocks.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus for controlling a flash memory, wherein the flash memory includes a plurality of blocks and the blocks are divided into a plurality of storage blocks and a plurality of spare blocks, the apparatus comprising:
a bad block mapping table; and
a controller for determining whether a block corresponding to an accessed block address is a damaged block when accessing a data based on the accessed block address, searching repeatedly the bad block mapping table to find the address of the corresponding spare block for replacing the accessed block address when the block corresponding to the accessed block address is the damaged block until the spare block corresponding to the accessed block address is a normal block, and accessing the data based on the accessed block address.

2. The apparatus as claimed in claim 1, wherein the bad block mapping table includes a plurality of mapping units, each said mapping unit includes a damaged block address storage area and a spare block address storage area, and the controller scans the address of damaged block stored in the damaged block address storage area for every said mapping unit to find the address of the corresponding spare block in the corresponding spare block address storage area as the accessed block address when the controller searches the bad block mapping table for the accessed block address.

3. The apparatus as claimed in claim 2, wherein the controller scans all the storage blocks at start-up of the apparatus, stores the addresses of damaged blocks into the damaged block address storage areas of the mapping units, and allocates a block among the spare blocks and stores the address of the block into the spare block address storage area of the mapping unit.

4. The apparatus as claimed in claim 2, comprising a newly added mapping unit is selected from the mapping units which are unused if the block corresponding to the accessed block address is the damaged block and the controller cannot find the accessed block address in the bad block mapping table, then the controller stores the accessed block address into the damaged block address storage area of the newly added mapping unit and allocates a block among the spare blocks to store the address of the spare block into the spare block address storage area of the newly added mapping unit.

5. The apparatus as claimed in claim 1, further comprising:
a register, used for providing a starting address of spare block in the spare blocks.

6. The apparatus as claimed in claim 5, wherein the bad block mapping table including N damaged block address storage areas, each said damaged block address storage area can store the address of one damaged block respectively, wherein if the controller finds the address of the damaged block is stored in the K^{th} damaged block address storage area, the controller outputs the starting address of the spare block plus K as the accessed block address to find the corresponding spare block, N and K are both integers, and N>=K>=0.

7. The apparatus as claimed in claim 6, wherein the controller scans all the storage blocks to store the addresses of damaged blocks into the damaged block address storage areas which are unused, at start-up of the apparatus.

8. The apparatus as claimed in claim 6, wherein the controller sequentially stores the accessed block address into the damaged block address storage area which is unused if the block corresponding to the accessed block address is a damaged block and the controller cannot find the accessed block address in the bad block mapping table.

9. A method for controlling flash memory, wherein the flash memory includes a plurality of blocks, the blocks are divided into a plurality of storage blocks and a plurality of spare blocks, the method comprising:
providing a bad block mapping table;
determining whether the block corresponding to the accessed block address is a damaged block when accessing a data based on an accessed block address;
searching repeatedly for the address of the corresponding spare block in the bad block mapping table based on the accessed block address to replace the accessed block address if the block corresponding to the accessed block address is a damaged block until the spare block corresponding to the accessed block address is a normal block; and
accessing the data based on the accessed block address.

10. The method as claimed in claim 9, wherein the bad block mapping table includes:
a plurality of mapping units, each said mapping unit including a damaged block address storage area and a spare block address storage area.

11. The method as claimed in claim 10, wherein the address of the corresponding spare block is found by searching the bad block mapping table based on the accessed block address to replace the accessed block address if the block corresponding to the accessed block address is the damaged block, the method comprising:
scanning the addresses of damaged blocks stored in the damaged block address storage areas of the mapping units in the bad block mapping table to find the address of the corresponding spare block in the spare block address storage area as the accessed block address.

12. The method as claimed in claim 10, further comprising:
scanning all the storage blocks at start-up;
storing the addresses of bad blocks into the damaged block address storage areas of the mapping units;
allocating a block from the spare blocks; and
saving the address of the block into the spare block address storage area of the mapping unit.

13. The method as claimed in claim 10, further comprising:
selecting a newly added mapping unit from the mapping units which are unused if the block corresponding to the accessed block address is the damaged block and the accessed block address is not found in the bad block mapping table;
storing the accessed block address in the damaged block address storage area of the newly added mapping unit;
allocating a block from the spare blocks; and
saving the address of the block into the spare block address storage area of the newly added mapping unit.

14. The method as claimed in claim 9, wherein the bad block mapping table includes:
N damaged block address storage areas, and each said damaged block address storage area storing an address of damaged block.

15. The method as claimed in claim 14, further comprising:
providing a starting address of the spare block.

16. The method as claimed in claim 15, wherein if the block corresponding to the accessed block address is the damaged block, searching the bad block mapping table based on the accessed block address to find the address of the corresponding spare block for replacing the accessed block address, comprising:
outputting the starting address of the spare block plus K as the accessed block address if the address of the damaged block is stored in the K^{th} damaged block address storage area, wherein N and K are integers and N>=K>=0.

17. The method as claimed in claim 16, further comprising:
scanning sequentially all the storage blocks at start-up; and
storing the addresses of the damaged blocks into the damaged block address storage areas which are unused.

18. The method as claimed in claim 16, further comprising:
the controller sequentially stores the accessed block address into the damaged block address storage area which is unused if the block corresponding to the accessed block address is the damaged block and the accessed block address is not found in the bad block mapping table.
